(19) United States
(12) Patent Application Publication
(10) Pub. No.: US 2011/0268144 A1
(43) Pub. Date: Nov. 3, 2011

(54) NITRIDE SEMICONDUCTOR LASER DEVICE

(76) Inventors: Kazutoshi Onozawa, Osaka (JP); Satoshi Tamura, Osaka (JP); Hideki Kasugai, Osaka (JP)

(21) Appl. No.: 12/681,981

(22) PCT Filed: Oct. 21, 2009
(86) PCT No.: PCT/JP2009/005510

§ 371 Date: Apr. 7, 2010

(30) Foreign Application Priority Data
Mar. 11, 2009 (JP) 2009-058647

(51) Int. Cl. H01S 5/323; H01S 5/00

(52) U.S. Cl. 372/45.01

(57) ABSTRACT

A nitride semiconductor laser device includes an active layer 106 made of a nitride semiconductor formed on a substrate and a current confining layer 109 formed above the active layer 106. The current confining layer has an opening 109a through which a current selectively flows into the active layer 106. The device satisfies 0.044<Δn/Γv<0.062 where Δn is the effective refractive index difference between the opening 109a and the current confining layer 109 and Γv is the vertical optical confinement factor as the proportion of laser light confined in the active layer 106 to laser light emitted in the active layer 106.

### TECHNICAL FIELD

The present disclosure relates to a self-pulsating nitride semiconductor laser device having a buried current confinement structure.

### BACKGROUND ART

Currently, research and development of blue-violet semiconductor laser devices using nitride semiconductors is being actively conducted for use in image recording/playback apparatuses for Blu-ray Discs (registered trademark) and the like. In high-density optical disc systems such as Blu-ray Discs, it is necessary to reduce optical feedback noise of laser light. As one of measures taken to reduce optical feedback noise, there is a technique of bringing a semiconductor laser device into self-pulsating operation.

To bring a semiconductor laser device into self-pulsation, a method is proposed in which a saturable absorption layer is placed in an optical guide layer or a cladding layer. When the saturable absorption layer is damaged with doping, dry etching, or the like, the carrier lifetime is effectively shortened, permitting self-pulsating operation (see Patent Document 1, for example).

### CITATION LIST

PATENT DOCUMENT 1: Japanese Patent Publication No. 2007-300016

### SUMMARY OF THE INVENTION

### Technical Problem

However, the conventional self-pulsating semiconductor laser device having a saturable absorption layer in an optical guide layer or a cladding layer has a problem that self-pulsating operation becomes unstable with temperature change. Moreover, in a ridge structure, which is normally formed for current confinement, the ridge depth tends to vary because the ridge is formed by dry etching. Such variations in ridge depth also cause instability of self-pulsating operation. Accordingly, the conventional self-pulsating nitride semiconductor laser device has a large problem to be solved before being mass-produced.

It is an object of the present disclosure to provide a nitride semiconductor laser device that conducts stable self-sustained pulsation and of which fabrication is easy.

### Solution to the Problem

To attain the above object, according to the present disclosure, the nitride semiconductor laser device is configured so that the ratio of the effective refractive index difference between a current confining layer and an opening to the vertical optical confinement factor is a predetermined value.

Specifically, the illustrative self-pulsating nitride semiconductor laser device includes: an active layer made of a nitride semiconductor formed on a substrate; and a current confining layer formed above the active layer, the current confining layer having an opening through which a current selectively flows into the active layer, wherein 0.044<Δn/Γv<0.062 is satisfied where Δn is an effective refractive index difference between the opening and the current confining layer, and Γv is a vertical optical confinement factor as a proportion of laser light confined in the active layer to laser light emitted in the active layer.

The illustrative self-pulsating nitride semiconductor laser device satisfies 0.044<Δn/Γv<0.062. When this condition is satisfied, each of portions on both sides of a current injected region of the active layer can be used as a saturable absorption region having a size suitable for self-sustained pulsation. Accordingly, a nitride semiconductor device that performs stable self-pulsating operation can be implemented. Also, with no need to form a ridge by dry etching, the device can be fabricated easily.

In the illustrative self-pulsating nitride semiconductor laser device, the current confining layer may be made of a compound represented by general formula AlₓGa₁₋ₓN (0.08≦x≦0.20) and including an n-type impurity.

### Advantages of the Invention

According to the present disclosure, a self-pulsating nitride semiconductor laser device having stable characteristics can be implemented.

### BRIEF DESCRIPTION OF THE DRAWINGS

FIG. 1 is a cross-sectional view of an illustrative self-pulsating nitride semiconductor laser device.

FIG. 2 includes cross-sectional views showing stepwise a method for fabricating the illustrative self-pulsating nitride semiconductor laser device.

FIG. 3 is a diagrammatic view shown to describe the effective refractive index difference and the vertical optical confinement factor.

FIG. 4 is a graph showing the relationship of the effective refractive index difference and the vertical optical confinement factor with self-sustained pulsation.

FIGS. 5(a) and 5(b) show the operation state observed when the condition of 0.044<Δn/Γv<0.062 is satisfied, where (a) is a graph showing an optical output waveform and (b) is a graph showing an pulsation spectrum.

FIGS. 6(a) and 6(b) show the operation state observed when the condition of 0.062≦Δn/Γv is satisfied, where (a) is a graph showing an optical output waveform and (b) is a graph showing an pulsation spectrum.

FIGS. 7(a) and 7(b) show the operation state observed when the condition of 0.044≧Δn/Γv is satisfied, where (a) is a graph showing an optical output waveform and (b) is a graph showing an pulsation spectrum.

### DESCRIPTION OF EMBODIMENTS

A blue-violet semiconductor laser is suitable as a light source for high-density optical discs, but has a problem that optical feedback noise occurs due to return light from an optical disc in playback of the disc. The present inventors have conducted intensive research to solve problems such as the optical feedback noise by focusing attention on nitride semiconductor laser devices having a buried current confining layer. As a result, the inventors have found that a self-pulsating nitride semiconductor laser device having stable characteristics can be implemented when the condition represented by Expression (1) below is satisfied.

0.044<Δn/Γv<0.062 (1)

where Δn denotes an effective refractive index difference, or the difference between the effective refractive index n1 of a current confining layer and the effective refractive index n2 of an opening formed through the current confining layer, and Γv denotes a vertical optical confinement factor, or the proportion of the laser light confined in an active layer to the laser light emitted in the active layer and distributed vertically.

An embodiment of the present disclosure will be described hereinafter in detail with reference to the accompanying drawings. Throughout the drawings, any components having substantially the same function are denoted by the same reference numeral, for simplicity of description. It should be noted that the present invention is not limited to the embodiment to follow.

### Embodiment

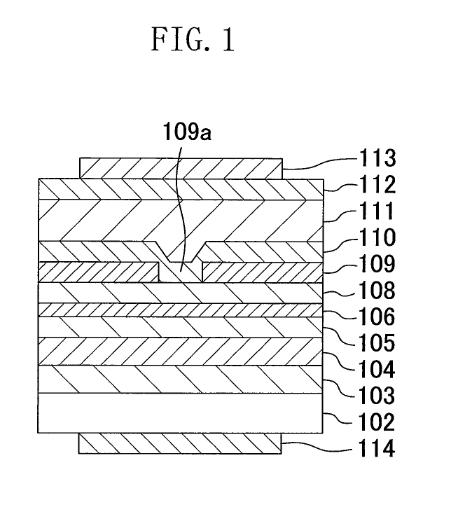

First, the configuration of a self-pulsating nitride semiconductor laser device of an embodiment will be described. FIG. 1 shows an example of the configuration of the self-pulsating nitride semiconductor laser device of the embodiment. As shown in FIG. 1, an n-GaN layer 103, an n-type cladding layer 104, an n-type guide layer 105, a multiple quantum well (MQW) active layer 106, a first p-type guide layer 108, and a current confining layer 109 are formed in this order on a 2-inch substrate 102 made of GaN. The compositions of the layers may be the same as those of general nitride semiconductor laser devices: for example, n-Al_{0.05}Ga_{0.95}N may be used for the n-type cladding layer 104, n-GaN for the n-type guide layer 105, InGaN for the active layer 106, p-GaN for the first p-type guide layer 108, and n-Al_{0.12}Ga_{0.88}N for the current confining layer 109. An overflow suppressing layer (not shown) made of p-Al_{0.15}Ga_{0.85}N may be included in the first p-type guide layer 108.

The current confining layer 109 has an opening 109a exposing the first p-type guide layer 108, and a second p-type guide layer 110 is re-grown on the current confining layer 109 so as to fill the opening 109a. The second p-type guide layer 110 may be made of p-GaN. On the second p-type guide layer 110, formed are a p-type cladding layer 111 made of p-Al_{0.05}Ga_{0.95}N and a p-type contact layer 112 made of p-GaN, for example. A p-type electrode 113 is formed on the p-type contact layer 112, and an n-type electrode 114 is formed on the surface of the substrate 102 on which no grown layers are formed.

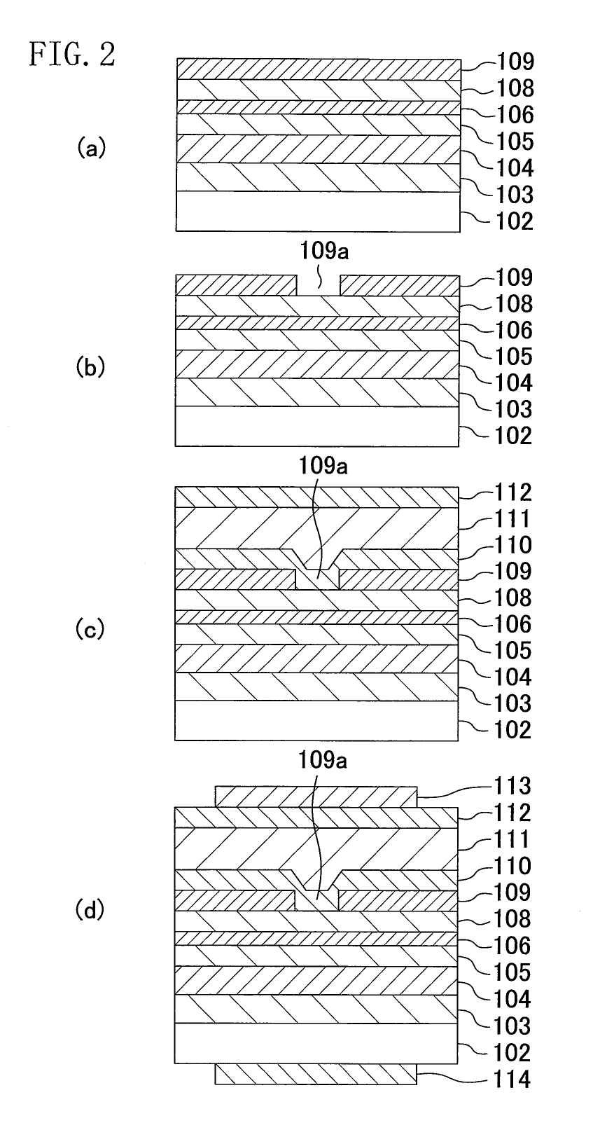

Next, a method for fabricating the self-pulsating nitride semiconductor laser device of this embodiment will be described. As shown in FIG. 2(a), the n-GaN layer 103, the n-type cladding layer 104, the n-type guide layer 105, the active layer 106, the first p-type guide layer 108, and the current confining layer 109 are grown sequentially on the 2-inch substrate 102 made of GaN.

Subsequently, as shown in FIG. 2(b), a portion of the current confining layer 109 is removed by photoelectrochemical (PEC) etching and the like, to form the opening 109a. By adopting PEC etching, stable etching can be made without fear of etching the underlying first p-type guide layer 108. During the PEC etching, the bottom surface of the substrate 102 should be covered with a protection film (not shown) such as an oxide film.

The PEC etching is performed by immersing the GaN substrate in an electrolytic solution while irradiating the current confining layer as the object to be etched with ultraviolet light from outside. With the ultraviolet irradiation, holes are generated on the surface of the current confining layer, causing dissolution reaction of the current confining layer with the generated holes, thus to perform etching. By use of the PEC etching, a buried nitride semiconductor laser device can be obtained stably.

Thereafter, as shown in FIG. 2(c), the second p-type guide layer 110 made of p-GaN, the p-type cladding layer 111 made of p-AlGaN, and the p-type contact layer 112 made of p-GaN are re-grown sequentially on the current confining layer 109 and on the portion of the first p-type guide layer 108 exposed in the opening 109a. The second p-type guide layer 110 is re-grown while a p-type impurity such as Mg is doped therein.

As shown in FIG. 2(d), activation annealing is performed in a nitride atmosphere at 780° C. for 20 minutes, to further reduce the resistance of the p-type layers. Thereafter, the p-type electrode 113 is formed on the p-type contact layer 112. The p-type electrode 113 is preferably made of a multilayer film including nickel (Ni) or palladium (Pd). Subsequently, the V-group surface of the substrate 102 is ground to thin the substrate 102, and then the n-type electrode 114 is formed on the ground surface. The n-type electrode 114 is preferably made of a multilayer film including titanium (Ti) or vanadium (v).

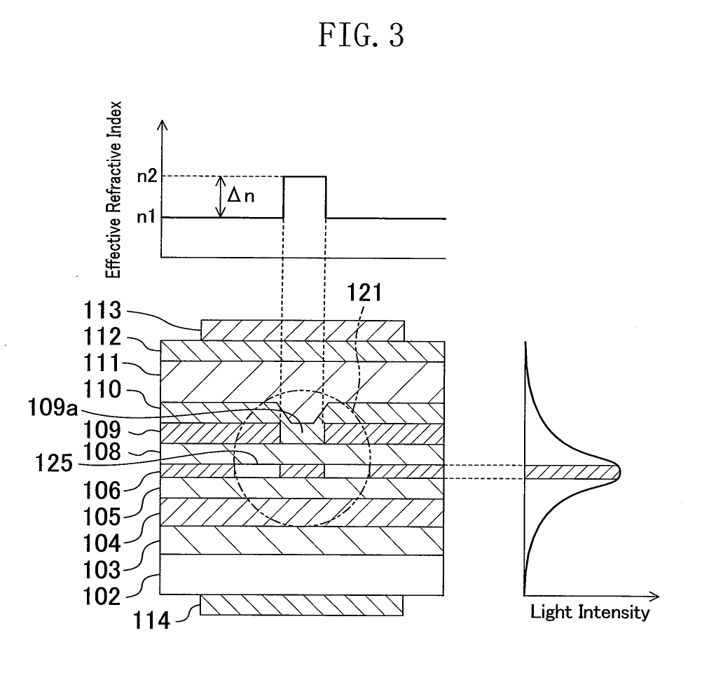

The semiconductor laser device of this embodiment is of a buried type, in which the current confining layer 109 has the opening 109a through which a current selectively flows into the active layer. Having this configuration, a current applied to the p-type electrode 113 is confined in the current confining layer 109 to flow through the portion of the opening 109a thereby to be injected into the active layer 106. However, as shown in FIG. 3, a emitting spot 121 spreads wider than the width of the opening 109a of the current confining layer 109. With this spread of the light, carriers are generated in portions of the active layer 106 located on both sides of the current injected region, forming a region where laser pulsation will occur only with injection of a small amount of current (saturable absorption region) in the active layer 106 under the current confining layer 109. With this region acting as the saturable absorption region 125, a self-pulsating semiconductor laser device can be implemented. To attain stable self-pulsating operation with the current diffusing laterally in the p-type guide layer 108 from the opening 109a, the saturable absorption region 125 must have a proper size. The size of the saturable absorption region 125 can be adjusted with the effective refractive index difference Δn between the current confining layer 109 and the opening 109a and the vertical optical confinement factor Γv. The effective refractive index difference Δn is the difference between the effective refractive index n1 of the current confining layer 109 and the effective refractive index n2 of the opening 109a.

Since the opening 109a is filled with the second p-type guide layer 110 made of p-GaN in this embodiment, the effective refractive index n2 of the opening 109a is determined mainly with the refractive index of GaN. Hence, n2 is larger than the effective refractive index n1 of the current confining layer 109 that is determined mainly with the refractive index of AlGaN. The vertical optical confinement constant Γv is the ratio of the laser light confined in the active layer 106 to the vertical distribution of the laser light emitted in the active layer 106.

In the semiconductor laser device having the configuration described above, the effective refractive index difference Δn between the current confining layer 109 and the opening 109a and the vertical optical confinement factor Γv can be changed with the thicknesses and compositions of the layers. For example, semiconductor laser devices having various values of the effective refractive index difference Δn and the vertical optical confinement factor Γv can be implemented by changing the Al content and thickness of the n-type cladding layer 104, the thickness of the n-type guide layer 105, the number of quantum wells (QWs) of the active layer 106, the thickness of the first-p-type guide layer 108, the Al content and thickness of the current confining layer 109, the thickness of the second p-type guide layer 110, the Al content and thickness of the p-type cladding layer 111, and the like.

Table 1 below shows some of actually fabricated semiconductor laser devices. In these examples, the thickness of the n-GaN layer 103 was 2 μm, the n-type cladding layer 104 was made of n-Al_{0.05}Ga_{0.95}N having a thickness of 1.6 μm, and the n-type guide layer 105 was made of n-GaN having a thickness of 150 nm. As the active layer 106, a combination of In_{0.10}Ga_{0.90}N having a thickness of 3 nm and In_{0.02}Ga_{0.98}N having a thickness of 7.5 nm was used as a pair. The first p-type guide layer 108 and the second p-type guide layer 110 were made of p-GaN, and the current confining layer 109 was made of n-AlₓGa₁₋ₓN. The opening 109a of the current confining layer 109 had a width of 1 μm. The p-type cladding layer 112 was made of p-Al_{0.05}Ga_{0.95}N having a thickness of 500 nm. In Table 1, the values of the effective refractive index difference Δn and the optical confinement factor Γv are those calculated based on the compositions and thicknesses of the layers. Note that the refractive indexes used for the calculation were 2.534 for GaN, 2.5005 for Al_{0.05}Ga_{0.95}N, and 2.4577 for Al_{0.12}Ga_{0.88}N.

TABLE 1

| No. | 1 | | 2 | | 3 | | 4 | | 5 | | 6 | | 7 | | 8 | |
|---|---|---|---|---|---|---|---|---|---|---|---|---|---|---|---|---|
| Active layer | 4 | pairs | 5 | pairs | 5 | pairs | 6 | pairs | 6 | pairs | 6 | pairs | 7 | pairs | 7 | pairs |
| Thickness of 1st p- | 165 | nm | 165 | mn | 165 | nm | 165 | nm | 165 | nm | 165 | nm | 133 | nm | 133 | nm |
| type guide layer | | | | | | | | | | | | | | | | |
| Thickness of current | 140 | nm | 140 | nm | 130 | nm | 130 | nm | 130 | nm | 130 | nm | 130 | nm | 130 | nm |
| confining layer | | | | | | | | | | | | | | | | |
| Thickness of 2nd p- | 35 | nm | 35 | nm | 61 | nm | 35 | nm | 89 | nm | 124 | nm | 76 | nm | 105 | nm |
| type guide layer | | | | | | | | | | | | | | | | |

| | | | | | | | | |
|---|---|---|---|---|---|---|---|---|
| Composition of | x = 0.15 | x = 0.13 | x = 0.12 | x = 0.15 | x = 0.12 | x = 0.12 | x = 0.12 | x = 0.12 |
| current confining | | | | | | | | |
| layer AlₓGa₁₋ₓN | | | | | | | | |
| Δn | 3.6 × 10⁻³ | 2.87 × 10⁻³ | 3.2 × 10⁻³ | 2.87 × 10⁻³ | 3.2 × 10⁻³ | 3.6 × 10⁻³ | 3.6 × 10⁻³ | 4 × 10⁻³ |
| Γv | 0.043 | 0.054 | 0.054 | 0.065 | 0.065 | 0.065 | 0.076 | 0.076 |

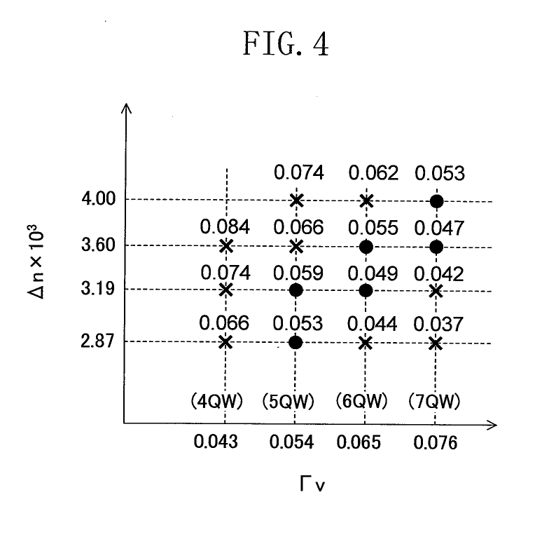

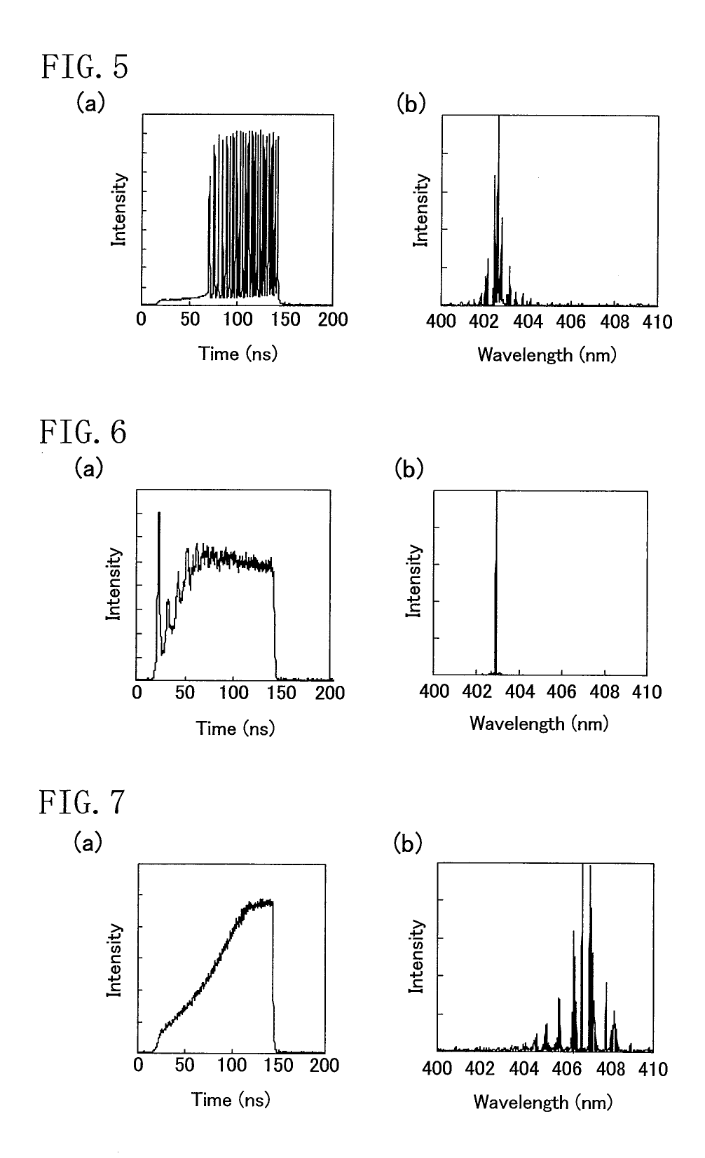

FIG. 4 is a graph with the y-axis representing Δn and the x-axis representing Γv, where the samples shown in Table 1 and other samples are plotted. In FIG. 4, symbol • indicates samples of which self-sustained pulsation was recognized, and symbol x indicates samples of which self-sustained pulsation was not recognized. The values of Δn/Γv of the respective samples are shown in the graph. As shown in FIG. 4, self-sustained pulsation was successful when the condition of 0.044<Δn/Γv<0.062 was satisfied. In this case, the optical output waveform changed with time as shown in FIG. 5(a). Also, a multi-mode pulsation spectrum was observed as shown in FIG. 5(b), exhibiting self-sustained pulsation. When Δn/Γv≧0.062, no change with time was observed in the optical output waveform as shown in FIG. 6(a). Also, a single-mode pulsation spectrum was observed as shown in FIG. 6(b). The reason for this is considered that, since the lateral spread of the emitting spot is small, the region of the active layer acting as the saturable absorption region is too small to cause self-sustained pulsation. When Δn/Γv≦0.044, no change with time was observed in the optical output waveform as shown in FIG. 7(a). Also, a multi-mode pulsation spectrum was observed as shown in FIG. 7(b). The reason for this is considered that since the lateral spread of the emitting spot is large, the region of the active layer acting as the saturable absorption layer is too large to cause self-sustained pulsation.

Although only the thicknesses of the guide layers and the current confining layer are changed for control of the values of Δn and Γv in Table 1, the compositions thereof may be changed. Also, although the thicknesses and compositions of the n-GaN layer 103, the n-type cladding layer 104, the n-type guide layer 105, and the p-type cladding layer 111 were kept unchanged, they may also be changed. Each of the layers can be formed of a compound represented by B_{w}AlₓIn_{y}Ga_{1-w-x-y}N (0≦w, x, y≦1, w+x+y≦1).

When the current confining layer 109 is made of AlₓGa₁₋ₓN, control of the value of the effective refractive index difference Δn will be easy as the Al content x of the current confining layer 109 increases and also the thickness thereof increases. However, if the Al content x of the current confining layer 109 is excessively large, cracking will easily occur. For example, when the Al content x is smaller than about 0.08, control of the effective refractive index difference Δn becomes difficult. Conversely, when the Al content x is higher than about 0.02, the possibility of occurrence of cracking increases. Accordingly, the Al content x of the current confining layer 109 should preferably be in the range of about 0.08 to about 0.20. As for the thickness of the current confining layer 109, it should preferably be in the range of about 50 nm to about 200 nm.

The value of the effective refractive index difference Δn should preferably be in the range of 2.87×10⁻³≦Δn≦4.00×10⁻³, and the optical confinement factor Γv should preferably be in the range of 0.054≦Γv≦0.076. The width of the opening 109a is not specifically limited. However, when the width is smaller than about 1 μm, the current flowing into the active layer 106 becomes excessively small. Conversely, when the width exceeds about 2 μm, the current injected region becomes so large that self-sustained pulsation is difficult. Accordingly, the width should preferably be in the range of about 1 μm to about 2 μm.

In FIG. 4, self-pulsating operation was not recognized when the quantum well active layer was made of four pairs of In_{0.10}Ga_{0.90}N having a thickness of 3 nm and In_{0.02}Ga_{0.98}N having a thickness of 7.5 nm. However, even a laser device having an active layer made of four or less pairs can be brought into self-pulsating operation by being configured so that Δn/Γv falls in the range of more than 0.044 to less than 0.062. This also applies to the case of eight pairs or more. Nevertheless, when the active layer 106 is made of five to seven pairs, the value of Δn/Γv can be easily made to fall in the range of more than 0.044 to less than 0.062. Although the active layer was given as a combination of two kinds of InGaN layers different in In content, it may be a combination of an InGaN layer and a GaN layer.

### INDUSTRIAL APPLICABILITY

The self-pulsating nitride semiconductor laser device of the present disclosure, which performs stable self-pulsating operation, is particularly useful as a laser device applied to an optical disc apparatus.

### DESCRIPTION OF REFERENCE CHARACTERS

102 Substrate
103 N—GaN Layer
104 N-type Cladding layer
105 N-type Guide Layer
106 Active layer
108 First P-type Guide Layer
109 Current confining Layer
109a Opening
110 Second P-type Guide Layer
111 P-type Cladding Layer
112 P-type Contact Layer
113 P-type Electrode
114 N-type Electrode
121 Emitting Spot
125 Saturable Absorption Region

1. A self-pulsating nitride semiconductor laser device, comprising:
an active layer made of a nitride semiconductor formed on a substrate; and
a current confining layer formed above the active layer, the current confining layer having an opening through which a current selectively flows into the active layer, wherein
0.044<Δn/Γv<0.062 is satisfied where Δn is an effective refractive index difference between the opening and the current confining layer, and Γv is a vertical optical confinement factor as a proportion of laser light confined in the active layer to laser light emitted in the active layer.

2. The self-pulsating nitride semiconductor laser device of claim 1, wherein
the current confining layer is made of a compound represented by general formula AlₓGa₁₋ₓN (0.08≦x≦0.20) and including an n-type impurity.
